(19) United States
(12) Patent Application Publication
(10) Pub. No.: US 2025/0271510 A1
(43) Pub. Date: Aug. 28, 2025

(54) METHOD, DEVICE AND SYSTEM FOR DETECTING SINGLE-PHASE BROKEN CONDUCTOR

(71) Applicant: Schneider Electric Industries SAS, Rueil-Malmaison (FR)

(72) Inventor: Jinlei Xing, Shanghai (CN)

(73) Assignee: Schneider Electric Industries SAS, Rueil-Malmaison (FR)

(21) Appl. No.: 18/893,327

(22) Filed: Sep. 23, 2024

(30) Foreign Application Priority Data
Feb. 28, 2024 (CN) 202410225526.3

(51) Int. Cl. G01R 31/58

(52) U.S. Cl. CPC G01R 31/58

(57) ABSTRACT

The present disclosure provides a method, a device and a system for detecting a single-phase broken conductor. The method includes: collecting a three-phase current at a measurement point; obtaining a positive sequence current and a negative sequence current from the collected three-phase current; calculating a change of the positive sequence current and a change of the negative sequence current within a first time interval; and when an amplitude of the positive sequence current decreases, an amplitude of the negative sequence current increases, a decrease of the amplitude of the positive sequence current is greater than a first predetermined value, and a ratio of a magnitude of change of the negative sequence current to a magnitude of change of the positive sequence current is greater than a second predetermined value, determining that a first set of faults occur, the first set of faults including a single-phase broken conductor.

### CROSS-REFERENCE TO RELATED APPLICATION(S)

This application claims priority of the Chinese Patent Application No. 202410225526.3 filed on Feb. 28, 2024, the content disclosed in which is incorporated herein by reference in their entirety.

### TECHNICAL FIELD

The present disclosure relates to broken conductor detection, in particular to a method, a device and a system for detecting a single-phase broken conductor in a power system.

### BACKGROUND

A broken conductor fault may occur in the power system due to various factors (for example, aging of lines, extreme weather, etc.). When the broken conductor fault occurs in the power system, the system voltage will change obviously, which affects not only the stable operation of the system, but also the normal operation of the electricity consumers in the system. In addition, in some cases, the broken conductor may be downed to the ground during the broken conductor fault, which not only threatens the lives of humans and animals around but also easily causes wildfires. Therefore, it is necessary to detect the broken conductor fault accurately and timely.

Some conventional methods for detecting a single-phase broken conductor have low accuracy or high cost.

### SUMMARY

The present disclosure provides a method, a device, and a system for detecting a single-phase broken conductor, which have high accuracy and low cost.

According to an aspect of the present disclosure, there is provided a single-phase broken conductor detection method comprising: collecting a three-phase current at a measurement point; obtaining a positive sequence current and a negative sequence current from the collected three-phase current; calculating a change of the positive sequence current and a change of the negative sequence current within a first time interval; and when an amplitude of the positive sequence current decreases, an amplitude of the negative sequence current increases, a decrease of the amplitude of the positive sequence current is greater than a first predetermined value, and a ratio of a magnitude of change of the negative sequence current to a magnitude of change of the positive sequence current is greater than a second predetermined value, determining that a first set of faults occur, the first set of faults including a single-phase broken conductor.

In some embodiments, the ratio of the magnitude of change of the negative sequence current to the magnitude of change of the positive sequence current is defined as: a ratio of an increase of the amplitude of the negative sequence current to the decrease of the amplitude of the positive sequence current; or a ratio of a modulus of a vector change of the negative sequence current to a modulus of a vector change of the positive sequence current.

In some embodiments, the method further comprises: collecting a three-phase voltage at the measurement point; obtaining a negative sequence voltage from the collected three-phase voltage; calculating a change of the negative sequence voltage within the first time interval; and when a modulus of a vector change of the negative sequence voltage is less than or equal to a third predetermined value, or when a difference between a phase angle of a vector change of the negative sequence current and a phase angle of the vector change of the negative sequence voltage is not within a predetermined range, determining that a downstream single-phase broken conductor in a line where the measurement point is located occurs.

In some embodiments, the method further comprises: after determining that the downstream single-phase broken conductor occurs, calculating a change value of the amplitude of the negative sequence current after a preset operation delay from the occurrence of the single-phase broken conductor relative to the amplitude of the negative sequence current before the occurrence of the single-phase broken conductor; when the change value is less than a fourth predetermined value, determining that the downstream single-phase broken conductor has been dealt with.

In some embodiments, the preset operation delay is set to be longer than a fault clearing time for other faults than the single-phase broken conductor.

In some embodiments, the first predetermined value is greater than or equal to a half of a maximum single-phase load current.

In some embodiments, the second predetermined value is greater than or equal to 0.8.

In some embodiments, the first time interval is 2 cycles of three-phase alternating current power.

According to an aspect of the present disclosure, there is provided a single-phase broken conductor detection device comprising: a collecting unit configured to collect a three-phase current at a measurement point; a storage unit configured to store data collected by the collecting unit; and a processing unit. The processing unit is configured to: obtain a positive sequence current and a negative sequence current from the collected three-phase current; calculate a change of the positive sequence current and a change of the negative sequence current within a first time interval; and when an amplitude of the positive sequence current decreases, an amplitude of the negative sequence current increases, a decrease of the amplitude of the positive sequence current is greater than a first predetermined value, and a ratio of a magnitude of change of the negative sequence current to a magnitude of change of the positive sequence current is greater than a second predetermined value, determine that a first set of faults occur, the first set of faults including a single-phase broken conductor.

According to an aspect of the present disclosure, there is provided a single-phase broken conductor detection system comprising a first single-phase broken conductor detection device and a second single-phase broken conductor detection device. Each of the first and second single-phase broken conductor detection devices includes: a collecting unit configured to collect a three-phase current and a three-phase voltage at a measurement point; a storage unit configured to store data collected by the collecting unit; and a processing unit. The processing unit is configured to: obtain a positive sequence current and a negative sequence current from the collected three-phase current; obtain a negative sequence voltage from the collected three-phase voltage; calculate a change of the positive sequence current and a change of the negative sequence current within a first time interval; calculate a change of the negative sequence voltage within the first time interval; when an amplitude of the positive sequence current decreases, an amplitude of the negative sequence current increases, a decrease of the amplitude of the positive sequence current is greater than a first predetermined value, and a ratio of a magnitude of change of the negative sequence current to a magnitude of change of the positive sequence current is greater than a second predetermined value, determine that a first set of faults occur, the first set of faults including a single-phase broken conductor; when a modulus of a vector change of the negative sequence voltage is less than or equal to a third predetermined value, or when a difference between a phase angle of a vector change of the negative sequence current and a phase angle of the vector change of the negative sequence voltage is not within a predetermined range, determine that a downstream single-phase broken conductor in a line where the measurement point is located occurs; after determining that the downstream single-phase broken conductor occurs, calculate a change value of the amplitude of the negative sequence current after a preset operation delay from the occurrence of the single-phase broken conductor relative to the amplitude of the negative sequence current before the occurrence of the single-phase broken conductor; and when the change value is less than a fourth predetermined value, determine that the downstream single-phase broken conductor has been dealt with. The second single-phase broken conductor detection device is located in the downstream of the first single-phase broken conductor detection device, and the preset operation delay for the second single-phase broken conductor detection device is shorter than that for the first single-phase broken conductor detection device.

According to the embodiments of the present disclosure, the single-phase broken conductor in the power system can be detected with high sensitivity and low cost.

### BRIEF DESCRIPTION OF DRAWINGS

These and/or other aspects, features and advantages of the present disclosure will become clearer and easier to understand from the following description of the embodiments taken in conjunction with the accompanying drawings, in which:

FIG. 1 is a simplified schematic diagram illustrating a part of a power system according to an embodiment of the present disclosure;

FIG. 2 is a flowchart illustrating a single-phase broken conductor detection method according to an embodiment of the present disclosure;

FIG. 3 is a flowchart illustrating a single-phase broken conductor detection method according to another embodiment of the present disclosure;

FIG. 4 is a flowchart illustrating a single-phase broken conductor detection method according to another embodiment of the present disclosure;

FIG. 5 is a block diagram illustrating a single-phase broken conductor detection device according to an embodiment of the present disclosure; and

FIG. 6 is a block diagram illustrating a single-phase broken conductor detection system according to an embodiment of the present disclosure.

### DETAILED DESCRIPTION

The present disclosure will be described in detail below with reference to example embodiments thereof. However, the present disclosure is not limited to the embodiments described herein, and can be implemented in many different forms. The described embodiments are only used to make the present disclosure thorough and complete, and fully convey the concept of the present disclosure to those skilled in the art. Features of the described embodiments may be combined or substituted with each other unless explicitly excluded or should be excluded according to the context.

A power system typically includes one or more power supplies, one or more substations, one or more transmission lines, and one or more electricity consumers. Three-phase alternating current power with three alternating currents of the same amplitude, the same frequency and an initial phase shift of 120 degrees may be generated by the three-phase power supply, and may be provided after transformation to various electricity consumers through the transmission lines. The power system may also include various devices for detecting parameters such as current, voltage and power in the power system. When a fault or an anomaly is detected in the power system, a relay action such as sending an alarm signal or directly isolating and cutting off the faulted part may be performed by a relay device.

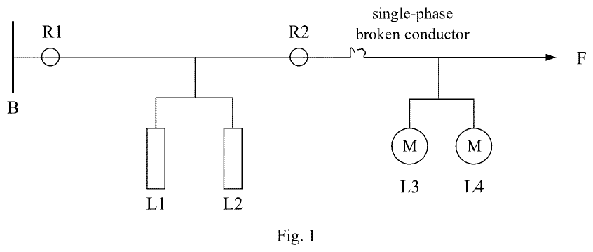

FIG. 1 is a simplified schematic diagram illustrating a part of a power system according to an embodiment of the present disclosure.

FIG. 1 illustrates a part of a power system, which includes a bus B, a feeder F led from the bus B, a plurality of loads L1-L4 connected to the feeder F, and single-phase broken conductor detection devices R1 and R2. The single-phase broken conductor detection devices R1 and R2 are used to detect whether a single-phase broken conductor occurs in the power system. Each of the single-phase broken conductor detection devices R1 and R2 may be implemented as a relay device, include a relay device, be included in a relay device, or be connected with a relay device. For example, the single-phase broken conductor detection devices R1 and R2 may perform relay actions, or may issue instructions of performing relay actions to cause the relay devices to perform the relay actions.

Although only one bus B, one feeder F led from the one bus B, and four loads L1-L4 are illustrated in FIG. 1, it should be understood that the number of lines and loads in the power system is not limited thereto. There may be multiple buses, there may be multiple feeders led from each bus, and each feeder may be connected to any number of loads. Each feeder may typically include an A-phase conductor, a B-phase conductor, a C-phase conductor and a neutral conductor. Although the feeder in FIG. 1 is only depicted in one line with an arrow, it should be understood that the feeder is not composed of only one conductor. In addition, although it is illustrated in FIG. 1 that the feeder is disconnected in the downstream of the relay R2, the disconnected part represents a single-phase broken conductor in the feeder, and does not mean that all conductors of the feeder are disconnected.

When the power system operates normally, the A-phase voltage, the B-phase voltage, and the C-phase voltage are symmetrical, the three-phase load of the line are substantially balanced, and the negative sequence current in the system is zero or substantially zero. In the process of operation, various faults such as a short circuit, a broken conductor, and the like may occur in the power system, and at this time, the three-phase symmetry of the system is destroyed. When a single-phase broken conductor occurs in a line, a first condition is satisfied, that is, an amplitude of a positive sequence current in the line decreases and the decrease is greater than a predetermined value; however, when other system faults such as a short circuit occur in the line, the amplitude of the positive sequence current in the line increases. Therefore, the single-phase broken conductor may be distinguished from some certain system faults in this line by the first condition.

In addition, when a single-phase broken conductor occurs in a line, a negative sequence current increases. Generally, when a single-phase broken conductor occurs, a magnitude of change of the negative sequence current is roughly the same as that of the positive sequence current. In an ideal situation, the magnitude of change of the negative sequence current may be equal to that of the positive sequence current. However, in some cases, such as when the load includes a motor, due to the inertia of the motor, after the single-phase broken conductor occurs, the magnitude of change of the negative sequence current will be greater than that of the positive sequence current. When a second condition is satisfied, that is, a ratio of the magnitude of change of the negative sequence current to the magnitude of change of the positive sequence current is greater than a predetermined value, it may be further determined that a single-phase broken conductor is very likely to occur in the line. For different power systems, different predetermined values may be set according to system parameters.

The faults detected according to the first and second conditions are not limited to a downstream single-phase broken conductor in the line where a measurement point is located, but may also be unbalanced faults in the upstream of the line where the measurement point is located or unbalanced faults in adjacent lines to the line where the measurement point is located, such as an upstream single-phase broken conductor in the line where the measurement point is located, and an inter-phase short circuit or single-phase grounding in adjacent lines to the line where the measurement point is located. A third condition may be further used to more accurately determine that the detected fault is the downstream single-phase broken conductor in the line where the measurement point is located, so that the relay device performs the relay action only in the case of the downstream single-phase broken conductor.

If the third condition is satisfied, that is, a ratio of a modulus of a vector change of the negative sequence voltage to a rated voltage is greater than a predetermined value and a difference between a phase angle of a vector change of the negative sequence current and a phase angle of the vector change of the negative sequence voltage is within a predetermined range, it may be determined that the fault detected according to the first and second conditions is an unbalanced fault in the upstream of the line where the measurement point is located or an unbalanced fault in adjacent lines to the line where the measurement point is located, rather than the downstream single-phase broken conductor in the line where the measurement point is located. At this time, the relay device corresponding to the measurement point is not allowed to perform the relay action. If the third condition is not satisfied, that is, the modulus of the vector change of the negative sequence voltage is less than or equal to a predetermined value (a third predetermined value), or the difference between the phase angle of the vector change of the negative sequence current and the phase angle of the vector change of the negative sequence voltage is not within the predetermined range, it is determined that the downstream single-phase broken conductor in the line where the measurement point is located occurs. At this time, the relay action may be performed.

In addition, in the power system, when a single-phase broken conductor occurs, it is desirable to perform the relay action in the shortest possible line length range, so as to minimize the impact on the whole line. For this end, a plurality of single-phase broken conductor detection devices may be disposed at different positions of the line, so that when a broken conductor fault occurs in the line, one of the single-phase broken conductor detection devices in the upstream of and closest to the faulted position first performs the relay action or issues the relay instruction according to the detection results.

For this end, when the first and second conditions are satisfied but the third condition is not, the single-phase broken conductor detection device does not immediately perform the relay action or issue the relay instruction, but waits for a preset operation delay. After the occurrence of a downstream single-phase broken conductor is determined, a change value of the amplitude of the negative sequence current after the preset operation delay from the occurrence of the single-phase broken conductor relative to the amplitude of the negative sequence current before the occurrence of the single-phase broken conductor is calculated. When the change value is less than a predetermined value, it indicates that the amplitude of the negative sequence current drops after the preset operation delay, which indicates that the downstream single-phase broken conductor has been dealt with, and thus the single-phase broken conductor detection device does not perform the relay action or issue the relay instruction. If the change value of the amplitude of the negative sequence current after the preset operation delay relative to the amplitude of the negative sequence current before the occurrence of the single-phase broken conductor is still greater than the predetermined value, it indicates that the single-phase broken conductor still exists, and thus the single-phase broken conductor detection device is required to perform the relay action or issue the relay instruction.

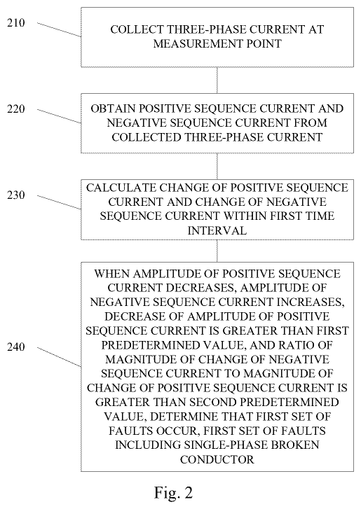

FIG. 2 is a flowchart illustrating a single-phase broken conductor detection method according to an embodiment of the present disclosure.

As illustrated in FIG. 2, the method includes: at step 210, a three-phase current at a measurement point is collected; at step 220, a positive sequence current and a negative sequence current are obtained from the collected three-phase current; at step 230, a change of the positive sequence current and a change of the negative sequence current within a first time interval are calculated; and at step 240, when an amplitude of the positive sequence current decreases, an amplitude of the negative sequence current increases, a decrease of the amplitude of the positive sequence current is greater than a first predetermined value, and a ratio of a magnitude of change of the negative sequence current to a magnitude of change of the positive sequence current is greater than a second predetermined value, it is determined that a first set of faults occur, the first set of faults including a single-phase broken conductor.

According to an embodiment, at step 210, the three-phase current of the power system may be measured by a single-phase broken conductor detection device (for example, R1 or R2 in FIG. 1). For example, the single-phase broken conductor detection device may be installed at the substation or a recloser, but it is not limited thereto. The single-phase broken conductor detection device may be disposed at any position of the line.

According to an embodiment, at step 220, the positive sequence current and the negative sequence current may be obtained from the collected three-phase current according to a method of symmetrical components. The method of symmetrical components is a commonly used method in power system analysis, and for the sake of brevity, this method is not described in detail here.

According to an embodiment, at step 230, the change of the positive sequence current may include a vector change and/or an amplitude change of the positive sequence current, and the change of the negative sequence current may include a vector change and/or an amplitude change of the negative sequence current.

The vector change of the positive sequence current may be expressed by the following equation 1:

$$Δ {\dot{I}}_{1} = {\dot{I}}_{1} ( t ) - {\dot{I}}_{1} ( t - Δ T 1 ) \qquad Equation 1$$

wherein, Δİ₁ represents the vector change of the positive sequence current within the first time interval ΔT1, İ₁ (t) represents the positive sequence current vector at time t, and İ₁(t−ΔT1) represents the positive sequence current vector at time t−ΔT1.

The amplitude change of the positive sequence current may be expressed by the following equation 2:

$$Δ {I}_{1} = \vert {\dot{I}}_{1} ( t ) \vert - \vert {\dot{I}}_{1} ( t - Δ T 1 ) \vert \qquad Equation 2$$

wherein, ΔI₁ represents the amplitude change of the positive sequence current within the first time interval ΔT1, |İ₁(t)| represents the amplitude of the positive sequence current at time t, and |İ₁(t−ΔT1)| represents the amplitude of the positive sequence current at time t−ΔT1.

The vector change of the negative sequence current may be expressed by the following equation 3:

$$Δ {\dot{I}}_{2} = {\dot{I}}_{2} ( t ) - {\dot{I}}_{2} ( t - Δ T 1 ) \qquad Equation 3$$

wherein, Δİ₂ represents the vector change of the negative sequence current within the first time interval ΔT1, İ₂(t) represents the negative sequence current vector at time t, and İ₂(t−ΔT1) represents the negative sequence current vector at time t−ΔT1.

The amplitude change of the negative sequence current may be expressed by the following equation 4:

$$Δ {I}_{2} = \vert {\dot{I}}_{2} ( t ) \vert - \vert {\dot{I}}_{2} ( t - Δ T 1 ) \vert \qquad Equation 4$$

wherein, ΔI₂ represents the amplitude change of the negative sequence current within the first time interval ΔT1, |İ₂(t)| represents the amplitude of the negative sequence current at time t, and |İ₂(t−ΔT1)| represents the amplitude of the negative sequence current at time t−ΔT1.

According to an embodiment, the first time interval ΔT1 may be 2 cycles of three-phase alternating current power.

According to an embodiment, at step 240, the ratio of the magnitude of change of the negative sequence current to the magnitude of change of the positive sequence current may be defined as the ratio |ΔI₂/ΔI₁| of the increase of the amplitude of the negative sequence current to the decrease of the amplitude of the positive sequence current, or may be defined as the ratio |Δİ₂|/|Δİ₁| of a modulus of the vector change of the negative sequence current to a modulus of the vector change of the positive sequence current.

According to an embodiment, at step 240, the first predetermined value may be a half of the maximum single-phase load current. According to an embodiment, the second predetermined value may be greater than or equal to 0.8. In particular, the second predetermined value may be set as 0.9.

Since the magnitude of change of the negative sequence current is roughly the same as or greater than the magnitude of change of the positive sequence current when the single-phase broken conductor occurs, this method has a high accuracy in detecting the single-phase broken conductor. In addition, since the single-phase broken conductor may be detected only by the data collected at the measurement point without other means such as communication between detection devices, the cost of detecting the single-phase broken conductor by this method is low.

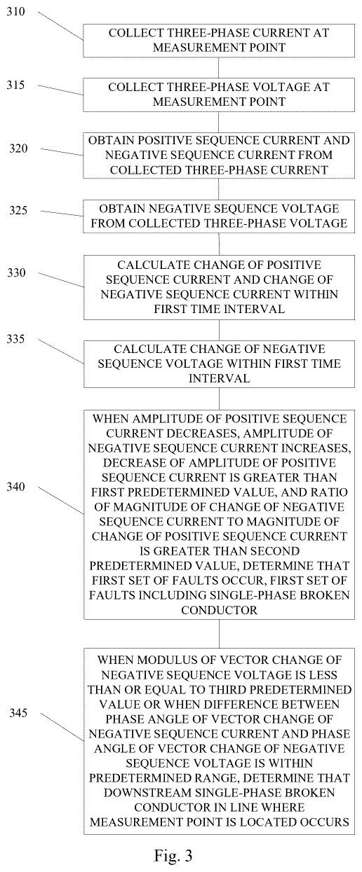

FIG. 3 is a flowchart illustrating a single-phase broken conductor detection method according to another embodiment of the present disclosure.

As illustrated in FIG. 3, the method includes: at step 310, a three-phase current at a measurement point is collected; at step 315, a three-phase voltage at the measurement point is collected; at step 320, a positive sequence current and a negative sequence current are obtained from the collected three-phase current; at step 325, a negative sequence voltage is obtained from the collected three-phase voltage; at step 330, a change of the positive sequence current and a change of the negative sequence current within a first time interval are calculated; at step 335, a change of the negative sequence voltage within the first time interval is calculated; at step 340, when an amplitude of the positive sequence current decreases, an amplitude of the negative sequence current increases, a decrease of the amplitude of the positive sequence current is greater than a first predetermined value, and a ratio of a magnitude of change of the negative sequence current to a magnitude of change of the positive sequence current is greater than a second predetermined value, it is determined that a first set of faults occur, and the first set of faults include a single-phase broken conductor; and at step 345, when a modulus of a vector change of the negative sequence voltage is less than or equal to a third predetermined value or a difference between a phase angle of a vector change of the negative sequence current and a phase angle of the vector change of the negative sequence voltage is within a predetermined range, it is determined that a downstream single-phase broken conductor in the line where the measurement point is located occurs.

The steps 310, 320, 330 and 340 of the single-phase broken conductor detection method illustrated in FIG. 3 are the same as steps 210, 220, 230 and 240 of the single-phase broken conductor detection method illustrated in FIG. 2, respectively, and therefore, repeated descriptions are omitted here.

According to an embodiment, at step 315, as with measuring the three-phase current, the three-phase voltage may be measured by the single-phase broken conductor detection device. Although measurements of the three-phase current and the three-phase voltage are described in two steps respectively, they may be measured at the same time.

According to an embodiment, at step 325, as with the method of obtaining the positive sequence current and the negative sequence current, the negative sequence voltage may be obtained from the collected three-phase voltage according to the method of symmetrical components. This method is not described in detail here.

According to an embodiment, at step 335, the change of the negative sequence voltage within the first time interval ΔT1 may include the vector change of the negative sequence voltage.

The vector change of the negative sequence voltage may be expressed by the following equation 5:

$$Δ {\dot{V}}_{2} = {\dot{V}}_{2} ( t ) - {\dot{V}}_{2} ( t - Δ T 1 ) \qquad Equation 5$$

wherein, Δ\dot{V}₂ represents the vector change of the negative sequence voltage within the first time interval ΔT1, \dot{V}₂(t) represents the negative sequence voltage vector at time t, and \dot{V}₂ (t−ΔT1) represents the negative sequence voltage vector at time t−ΔT1.

According to an embodiment, at step 345, it may be determined according to further conditions that the downstream single-phase broken conductor in the line where the measurement point is located occurs.

If the following condition (the third condition) is satisfied, that is, the ratio of the modulus of the vector change of the negative sequence voltage to the rated voltage is greater than a predetermined value and the difference between the phase angle of the vector change of the negative sequence current and the phase angle of the vector change of the negative sequence voltage is within a predetermined range, it may be determined that the detected fault is not the downstream single-phase broken conductor in the line where the measurement point is located, but an unbalanced fault in the upstream of the line where the measurement point is located or an unbalanced fault in adjacent lines to the line where the measurement point is located, such as an upstream single-phase broken conductor in the line where the measurement point is located, or inter-phase short circuit or single-phase grounding in adjacent lines to the line where the measurement point is located. At this time, the single-phase broken conductor detection device may lock the relay action. According to an embodiment, when the following inequation 1 and inequation 2 are satisfied at the same time, it may be determined that the detected fault is an unbalanced fault in the upstream of the line where the measurement point is located or an unbalanced fault in adjacent lines to the line where the measurement point is located.

$$\vert Δ {\dot{V}}_{2} \vert > 2 \% {V}_{n} \qquad Inequation 1$$

$$- 270 ° < Angle ( Δ {\dot{I}}_{2} ) - Angle ( - Δ {\dot{V}}_{2} ) - RCA < - 90 ° \qquad Inequation 2$$

wherein, |Δ\dot{V}₂ represents the modulus of the vector change of the negative sequence voltage, Vₙ represents the rated voltage in the line, Angle represents the phase angle, and RCA represents the relay characteristic angle (also known as the sensitive angle). RCA depends on the line impedance value and may be set by users according to actual situations. In addition, 2% in the inequation 1 is only an example, and may be set as other values by users according to actual situations.

When the above third condition is not satisfied, it may be determined that the detected fault is the downstream single-phase broken conductor in the line where the measurement point is located. That is, when the ratio of the modulus of the vector change of the negative sequence voltage to the rated voltage is less than or equal to the predetermined value, or when the difference between the phase angle of the vector change of the negative sequence current and the phase angle of the vector change of the negative sequence voltage is not within the predetermined range, it may be determined that the detected fault is the downstream single-phase broken conductor in the line where the measurement point is located. For example, when the following inequation 3 or inequation 4 is satisfied, it may be determined that the detected fault is the downstream single-phase broken conductor in the line where the measurement point is located.

$$\vert Δ {\dot{V}}_{2} \vert \leq 2 \% {V}_{n} \qquad Inequation 3$$

$$- 90 ° < Angle ( Δ {\dot{I}}_{2} ) - Angle ( - Δ {\dot{V}}_{2} ) - RCA < 90 ° \qquad Inequation 4$$

In an embodiment, after the single-phase broken conductor fault in the downstream is detected, the relay action may be performed, for example, the relay device corresponding to the measurement point performs the relay action or issues the relay instruction. In another embodiment, after the single-phase broken conductor fault in the downstream is detected, the relay action is not performed immediately, but a delay is waited and then further determination of whether to perform the relay action is made after the delay.

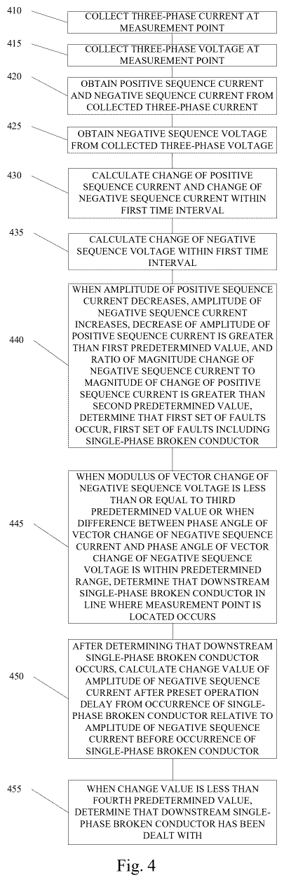

FIG. 4 is a flowchart illustrating a single-phase broken conductor detection method according to another embodiment of the present disclosure.

The single-phase broken conductor detection method illustrated in FIG. 4 is substantially the same as that illustrated in FIG. 3, except that it further includes: at step 450, after it is determined that the downstream single-phase broken conductor occurs, a change value of the amplitude of the negative sequence current after a preset operation delay from the occurrence of the single-phase broken conductor relative to the amplitude of the negative sequence current before the occurrence of the single-phase broken conductor is calculated; and at step 455, when the change value is less than a fourth predetermined value, it is determined that the downstream single-phase broken conductor has been dealt with. Steps 410, 415, 420, 425, 430, 435, 440 and 445 of the single-phase broken conductor detection method illustrated in FIG. 4 may be the same as steps 310 to 345 of the single-phase broken conductor detection method illustrated in FIG. 3, respectively, and therefore, repeated descriptions are omitted here.

According to an embodiment, at step 450, after the occurrence of the downstream single-phase broken conductor in the line where the measurement point is located is determined according to the previous steps, the single-phase broken conductor detection device does not immediately perform the relay action or issue the relay instruction, but waits for a preset operation delay. According to an embodiment, during the preset operation delay, a change of the amplitude of the negative sequence current may be focused on. For example, during the preset operation delay, the amplitude of the negative sequence current at present may be continuously compared with the amplitude of the negative sequence current before the occurrence of the single-phase broken conductor.

According to an embodiment, the operation delay may be set to be longer than a fault clearing time for other faults than the single-phase broken conductor, so as to ensure that the single-phase broken conductor detection device does not malfunction before the other faults are cleared. In addition, according to an embodiment, the operation delay may be set to be less than 3 s. Typically, the fault clearing time in the power system is less than 3 s, so too much time may be prevented from being wasted in waiting before performing the relay action, and thus the expansion of losses caused by the faults may be avoided.

According to an embodiment, at step 455, the change value being less than the fourth predetermined value indicates that the amplitude of the negative sequence current drops after the preset operation delay, which indicates that the downstream single-phase broken conductor has been dealt with, and therefore, the single-phase broken conductor detection device does not need to perform the relay action or issue the relay instruction. On the contrary, if the change value of the amplitude of the negative sequence current relative to the amplitude of the negative sequence current before the occurrence of the single-phase broken conductor is always greater than the fourth predetermined value during the preset operation delay, it indicates that the single-phase broken conductor still exists and has not been dealt with, and therefore, the single-phase broken conductor detection device is required to perform the relay action or issue the relay instruction.

According to the steps 450 and 455, since the preset operation delay was waited for at the measurement point at step 450, time may be left for the relay device in the downstream of the measurement point to deal with the fault. If the fault is dealt with by the downstream relay device within the preset operation delay for the measurement point, the relay device corresponding to the measurement point does not need to perform the relay action or issue the relay instruction for the fault. Therefore, the range of lines involved in the relay action may be reduced, so as to minimize the influence of the relay action on the whole line.

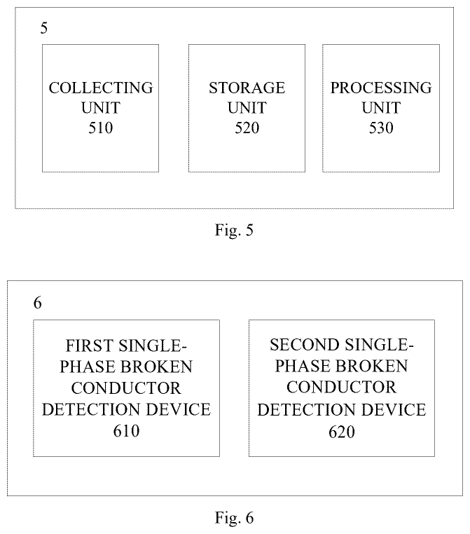

FIG. 5 is a block diagram illustrating a single-phase broken conductor detection device in a power system according to an embodiment of the present disclosure.

According to an embodiment, a single-phase broken conductor detection device 5 may include a collecting unit 510, a storage unit 520 and a processing unit 530. The collecting unit 510 may be configured to collect a three-phase current and a three-phase voltage at a measurement point. The storage unit 520 may be configured to store data collected by the collecting unit. The processing unit 530 may be configured to: obtain a positive sequence current and a negative sequence current from the collected three-phase current; calculating a change of the positive sequence current and a change of the negative sequence current within a first time interval; and when an amplitude of the positive sequence current decreases, an amplitude of the negative sequence current increases, a decrease of the amplitude of the positive sequence current is greater than a first predetermined value, and a ratio of a magnitude of change of the negative sequence current to a magnitude of change of the positive sequence current is greater than a second predetermined value, it is determined that a first set of faults occur, the first set of faults including a single-phase broken conductor.

According to an embodiment, the single-phase broken conductor detection device 5 may be a relay device, may include a relay device, may be included in a relay device, or may be connected with a relay device. When the single-phase broken conductor detection device 5 detects a single-phase broken conductor, the single-phase broken conductor detection device 5 may perform a relay action or issue a relay instruction.

Although it is described above that the collecting unit 510, the storage unit 520, and the processing unit 530 of the single-phase broken conductor detection device 5 execute the single-phase broken conductor detection method described with reference to FIG. 2, the present disclosure is not limited thereto. According to an embodiment, the collecting unit 510, the storage unit 520, and the processing unit 530 of the single-phase broken conductor detection device 5 may also execute the single-phase broken conductor detection method described with reference to FIG. 3 or FIG. 4.

FIG. 6 is a block diagram illustrating a single-phase broken conductor detection system according to an embodiment of the present disclosure.

According to an embodiment, the single-phase broken conductor detection system 6 may include a first single-phase broken conductor detection device 610 and a second single-phase broken conductor detection device 620. Each of the first and second single-phase broken conductor detection devices 610 and 620 may be the single-phase broken conductor detection device described with reference to FIG. 5.

The collecting unit of each of the first and second single-phase broken conductor detection devices 610 and 620 may be configured to perform the steps 410 and 415 in the single-phase broken conductor detection method described with reference to FIG. 4, and the processing unit of each of the first and second single-phase broken conductor detection devices 610 and 620 may be configured to perform the steps 420, 425, 430, 435, 440, 445, 450, and 455 in the single-phase broken conductor detection method described with reference to FIG. 4.

The second single-phase broken conductor detection device 620 may be located in the downstream of the first single-phase broken conductor detection device 610. For example, the second single-phase broken conductor detection device 620 may be located at R2 position in FIG. 1, and the first single-phase broken conductor detection device 610 may be located at R1 position in FIG. 1. The preset operation delay for the second single-phase broken conductor detection device 620 may be shorter than that for the first single-phase broken conductor detection device 610. Therefore, when the steps 450 and 455 of the single-phase broken conductor detection method described with reference to FIG. 4 are performed, the first single-phase broken conductor detection device 610 located upstream may wait for a longer delay than the second single-phase broken conductor detection device 620 located downstream. Therefore, when a single-phase broken conductor occurs at the position illustrated in FIG. 1, since the second single-phase broken conductor detection device 620 has a relatively shorter operation delay, it may obtain the detection result, and thus perform the relay action or issue the relay instruction more quickly. Since the single-phase broken conductor fault is dealt with by the second single-phase broken conductor detection device 620, the first single-phase broken conductor detection device 610 which is still waiting for the operation delay does not need to perform the relay action or issue the relay instruction any more. Therefore, the influence of the relay action on the whole line can be minimized.

All or part of the respective units (e.g., processing module) described in the present disclosure may be implemented in suitable hardware, software or a combination of hardware and software, for example, in a dedicated circuit, firmware, software or any combination thereof. For example, certain aspects may be implemented in hardware, while other aspects may be implemented in firmware or software that may be executed by a controller, a microprocessor or other computing devices. For example, the processing module in the present disclosure may include a micro-processing unit (MCU), which may operate in conjunction with software. The memory module of the present disclosure may be any suitable memory or storage area, which may be an independent unit or integrated in other units, such as a processing module.

The block diagrams of circuits, devices, apparatuses, equipments and systems involved in the present disclosure are only illustrative examples, and are not intended to require or imply that they must be connected, arranged and configured in the manner illustrated in the block diagram. As those skilled in the art will recognize, these circuits, devices, apparatuses, equipments, and systems may be connected, arranged and configured in any way, as long as the desired purpose may be achieved.

It should be understood by those skilled in the art that the above specific embodiments are only examples, not limitations, and various modifications, combinations, partial combinations and substitutions can be made to the embodiments of the present disclosure according to design requirements and other factors, as long as they are within the scope of the following claims or their equivalents, that is, they belong to the scope claimed by the present disclosure.

1. A single-phase broken conductor detection method, comprising:
collecting a three-phase current at a measurement point;
obtaining a positive sequence current and a negative sequence current from the collected three-phase current;
calculating a change of the positive sequence current and a change of the negative sequence current within a first time interval; and
when an amplitude of the positive sequence current decreases, an amplitude of the negative sequence current increases, a decrease of the amplitude of the positive sequence current is greater than a first predetermined value, and a ratio of a magnitude of change of the negative sequence current to a magnitude of change of the positive sequence current is greater than a second predetermined value, determining that a first set of faults occur, the first set of faults including a single-phase broken conductor.

2. The method according to claim 1, wherein the ratio of the magnitude of change of the negative sequence current to the magnitude of change of the positive sequence current is defined as:
a ratio of an increase of the amplitude of the negative sequence current to the decrease of the amplitude of the positive sequence current; or
a ratio of a modulus of a vector change of the negative sequence current to a modulus of a vector change of the positive sequence current.

3. The method according to claim 1, further comprising:
collecting a three-phase voltage at the measurement point;
obtaining a negative sequence voltage from the collected three-phase voltage;
calculating a change of the negative sequence voltage within the first time interval; and
when a modulus of a vector change of the negative sequence voltage is less than or equal to a third predetermined value, or when a difference between a phase angle of a vector change of the negative sequence current and a phase angle of the vector change of the negative sequence voltage is not within a predetermined range, determining that a downstream single-phase broken conductor in a line where the measurement point is located occurs.

4. The method according to claim 3, further comprising:
after determining that the downstream single-phase broken conductor occurs, calculating a change value of the amplitude of the negative sequence current after a preset operation delay from the occurrence of the single-phase broken conductor relative to the amplitude of the negative sequence current before the occurrence of the single-phase broken conductor;
when the change value is less than a fourth predetermined value, determining that the downstream single-phase broken conductor has been dealt with.

5. The method according to claim 4, wherein the preset operation delay is set to be longer than a fault clearing time for other faults than the single-phase broken conductor.

6. The method according to claim 1, wherein the first predetermined value is greater than or equal to a half of a maximum single-phase load current.

7. The method according to claim 1, wherein the second predetermined value is greater than or equal to 0.8.

8. The method according to claim 1, wherein
the first time interval is 2 cycles of three-phase alternating current power.

9. A single-phase broken conductor detection device, comprising:
a collecting unit configured to collect a three-phase current at a measurement point;
a storage unit configured to store data collected by the collecting unit; and
a processing unit configured to:
obtain a positive sequence current and a negative sequence current from the collected three-phase current;
calculate a change of the positive sequence current and a change of the negative sequence current within a first time interval; and
when an amplitude of the positive sequence current decreases, an amplitude of the negative sequence current increases, a decrease of the amplitude of the positive sequence current is greater than a first predetermined value, and a ratio of a magnitude of change of the negative sequence current to a magnitude of change of the positive sequence current is greater than a second predetermined value, determine that a first set of faults occur, the first set of faults including a single-phase broken conductor.

10. A single-phase broken conductor detection system, comprising:
a first single-phase broken conductor detection device and a second single-phase broken conductor detection device, each of the first and second single-phase broken conductor detection devices being the single-phase broken conductor detection device according to claim 9,
wherein the collecting unit of each of the first and second single-phase broken conductor detection devices is further configured to collect a three-phase voltage at the measurement point,
wherein the processing unit of each of the first and second single-phase broken conductor detection devices is further configured to:
obtain a negative sequence voltage from the collected three-phase voltage;
calculate a change of the negative sequence voltage within the first time interval;
when a modulus of a vector change of the negative sequence voltage is less than or equal to a third predetermined value, or when a difference between a phase angle of a vector change of the negative sequence current and a phase angle of a vector change of the negative sequence voltage is not within a predetermined range, determine that a downstream single-phase broken conductor in a line where the measurement point is located occurs;
after determining that the downstream single-phase broken conductor occurs, calculate a change value of the amplitude of the negative sequence current after a preset operation delay from the occurrence of the single-phase broken conductor relative to the amplitude of the negative sequence current before the occurrence of the single-phase broken conductor; and
when the change value is less than a fourth predetermined value, determine that the downstream single-phase broken conductor has been dealt with,
wherein the second single-phase broken conductor detection device is located in the downstream of the first single-phase broken conductor detection device, and the preset operation delay for the second single-phase broken conductor detection device is shorter than that for the first single-phase broken conductor detection device.
